(19) United States
(12) Patent Application Publication
(10) Pub. No.: US 2002/0100417 A1
(43) Pub. Date: Aug. 1, 2002

(54) HEATING-TYPE TRAP DEVICE AND FILM-DEPOSITION APPARATUS

(76) Inventors: JUN-ICHI SUZUKI, TOKYO (JP); SATOSHI KAKIZAKI, TOKYO (JP)

Correspondence Address: McGinn & Gibb, P.C., 8321 Old Courthous Road, Suite 200, Vienna, VA, 22182-3817, US

(21) Appl. No.: 09/335,720

(22) Filed: Jun. 18, 1999

(30) Foreign Application Priority Data
Jun. 18, 1998 (JP) 10-171678
May 25, 1999 (JP) 11-144662

(51) Int. Cl. C23C 16/00

(52) U.S. Cl. 118/715

(57) ABSTRACT

A heating-type trap device for being fitted in between a film-deposition apparatus and an exhaust piping, and for removing residual film-deposition components from exhaust gases discharged through the exhaust piping from the film-deposition apparatus, includes a trap portion for receiving the exhaust gases, and a plurality of plate heaters disposed within the trap portion, to define a zigzag pathway for the exhaust gases passing therethrough.

### BACKGROUND OF THE INVENTION

1. Field of the Invention

The present invention relates to a heating-type trap device and a film-deposition apparatus, and more particularly to a heating type trap device fitted in between a film-deposition chamber and an exhaust piping and for use in removing residual film-deposition components out of gases which have already been used for a film-deposition in a film-deposition chamber and discharged therefrom into the exhaust piping, and a film-deposition apparatus equipped with the heating-type trap device thus constructed.

2. Description of the Related Art

FIG. 3 is a schematic diagram showing a cross-sectional view of a typical vertical chemical vapor deposition (CVD) apparatus as a conventional film-deposition apparatus disposed in a housing, as well as its exhaust piping for discharging exhaust gas out of the housing. In the vertical CVD apparatus, a reaction tube 110 defining a film-deposition chamber includes a base portion 111, an outer tube 112 and an inner tube 113. Between the outer and inner tubes 112 and 113, there is provided a gap or space to define a dual structure. To heat an interior of the reaction tube 110, a heater 120 is provided around the outer tube 112.

A bottom portion of the reaction tube 110 is selectively sealed by a bottom lid 130. On a side wall of the base portion 111 is provided a gas inlet hole 114 through which reactive gases (such as SiH₄, Si₂H₆, SiH₂Cl₂, NH₃, PH₃, N₂O, or TEOS) are introduced thereinto as indicated by an arrow in FIG. 3 for a film-deposition (such as poly-Si, SiO₂, or Si₂N₄). An exhaust gas outlet hole 115 is provided on the same side wall but in a diametrically opposed manner to the gas inlet hole 114.

In operation of the above-mentioned vertical CVD apparatus, a boat 140 for mounting a plurality of wafers 141 to be processed is disposed on the bottom lid 130. Reactive gases enter the inner tube 113 along an arrow as indicated in FIG. 3 so as to deposit or form a film on each of wafers 141, and then pass through the gap formed between the inner tube 113 and the outer tube 112 to be evacuated from the exhaust gas hole 115. The exhaust gases flow through an exhaust piping 160 from the exhaust gas outlet hole 115, and then are discharged by a vacuum pump or the like of an evacuation system (not shown).

However, the exhaust gases may include reacted byproducts and unreacted gases (hereinafter, referred to as “residual film-deposition components”). As a result, byproducts 160a (such as C₂H₄, HCl, P₂O₅, (SiO₂)n, or NH₄Cl) may be disadvantageously deposited on an inner surface of the exhaust piping 160a, as indicated by diagonally shaded areas in FIG. 3. Thus, such byproducts may be deposited on downstream portions of the exhaust pipe 160 near the exhaust gas outlet hole 115 and in some cases interior portions of the vacuum pump.

If the deposition of such by-products occurs in the exhaust pipe 160, a pathway for the exhaust gases is narrowed, thereby adversely affecting the pressure in the film-deposition chamber over time and consequently lowering film deposition yields on wafers. Also, if by-products deposited on the exhaust piping partially flake off, the flakes may be scattered (e.g., reversely diffused), and will contaminate an interior of the film-deposition chamber (i.e., an interior of the reaction tube 110). In addition, if such flakes adhere to the interior of the vacuum pump and so on, such equipment would consequently have a shorter service life.

Hence, it has been proposed that residual film-deposition components be trapped by a water-cooled trap device or cold trap device 170, as shown in FIGS. 4(a) and 4(b). The trap device 170 flows cooling water internally for cooling a mesh 171 disposed in the trap device. As a result, residual film-deposition components of the exhaust gases are deposited as a film(s) onto the mesh, so that the trap device 170 can remove residual film-deposition components from the exhaust gases. In this case, although it may be possible to reduce the adhesion or deposition due to residual components onto the exhaust piping 160 and any apparatus disposed downstream of the trap device 170, deposited films or adherents partially flake-off from the trap device 170 due to a low adhering strength. As a result, the interior of the film deposition chamber may be contaminated by flaked-off adherents or particles (e.g., reverse diffusion of such particles). Also, upon checking of leakage, an apparent amount of leakage may be increased by degassing from deposited films and adherents depending upon the types of gases used.

This phenomenon occurs as follows. For example, in the case of Si₃N₄, NH₄Cl (ammonium chloride) is deposited as a film to a low temperature portion as a byproduct which has a high moisture absorbency, and will absorb moisture in the air upon mixture therewith. Therefore, if evacuated, this moisture is outgassed so that a vacuum state cannot be obtained (e.g., due to its degassing). Thus, it appears as if a leakage has developed.

Instead of the above cold trap device, a multi-trap device 180 has been proposed as shown in FIG. 5 which does not employ cooling water. In this multi-trap device 180, an exhaust pathway 181 is multiply folded-back, so as to make the pathway longer and permit byproducts to be deposited in such an elongated pathway and so as to catch the byproducts as much as possible. However, such a device is large and requires a large installation space. Similarly to the above device shown in FIGS. 4(a) and 4(b), the residual film-deposition components and the like are disadvantageously deposited in the exhaust piping 160 in a region ranging from an exhaust gas hole to the multi-trap device 180.

Also, a method has been proposed for keeping a temperature (e.g., about 100° C. through about 120° C.) of an exhaust piping 160A extending from an exhaust gas hole of a film deposition apparatus so as to avoid an occurrence of reacted byproducts and to avoid a film-deposition in that piping range, as shown in FIG. 6. In this case, a piping heater 185 and heating valve (or hot valve) 186 must be disposed for heating the piping extending from the exhaust gas hole. However, the overall device is complicated and the residual film-deposition components are disadvantageously deposited in various components, including a vacuum pump, disposed downstream of the hot valve 186. Thus, the components, including the vacuum pump, have a shorter service life.

With the trap devices of conventional film-deposition apparatuses mentioned above, it is thus impossible to permit residual film-deposition components to be sufficiently deposited in the trap device. As a result, an interior of the film-deposition apparatus is insufficiently prevented from being contaminated by particles flaked off or away from the trap device and so on. Also, the trap device must be disadvantageously made large and complicated in structure to trap the residual components and the like, and also has an increased manufacturing cost.

### SUMMARY OF THE INVENTION

In view of the foregoing and other problems of the conventional systems and methods, an object of the present invention is to provide a trap device and a film-deposition apparatus at a moderate manufacturing cost. The trap device is adapted for surely or sufficiently depositing residual film-deposition components and the like on a trap portion. As a result, an interior of the film-deposition apparatus is prevented from being contaminated by flaked-off particles, without increasing the size and complexity of the overall trap device for trapping residual film-deposition components and without requiring additional facilities for trapping the residual film-deposition components and the like.

To achieve the above-mentioned and other objects, the present invention provides a heating-type trap device adapted for being fitted between a film-deposition apparatus and an exhaust piping for removing residual film-deposition components from exhaust gases which are discharged through the exhaust piping from the film-deposition apparatus, wherein a plurality of plate-like heaters are disposed within a trap portion of the trap device to define a zigzag or folded-back (e.g., a snake-like or serpentine shape) pathway for exhaust gases passing therethrough.

With this arrangement, a heating source outside of the exhaust piping is unnecessary. Since the zigzag pathway is arranged in the heating-type trap device, it is possible to minimize the size of the heating-type trap device and to increase the trapping effect with respect to the residual film-deposition components of the exhaust gases. Also, since plate-like heaters are arranged adjacent to each other, heating efficiency is improved so that the film-deposition components and the like can be sufficiently deposited thereon with minimum energy-consumption. As a result, it is possible to reduce a manufacturing cost per chip.

Also, the present invention provides a trap temperature-presetting mechanism including the plate-like heaters and adapted for presetting an interior temperature of the heating-type trap device at a temperature equal to or greater than a film-deposition temperature of the film-deposition apparatus.

With this configuration, since residual film-deposition gases of the exhausted gases discharged from the film-deposition apparatus are heated to the film-deposition temperature in the heating-type trap device, the residual film-deposition gases will be deposited on inner walls of the heating-type trap device in a manner similar to procedures used in the film-deposition apparatus. Accordingly, since a film(s) or layer(s) formed due to this film-deposition is strongly deposited or bonded onto inner walls of the heating-type trap device, there is no danger of the film(s) flaking off from the heating-type trap device.

Therefore, the interior of the film deposition apparatus will not be contaminated by the resultant flaked-off particles with adverse affects to a vacuum pump, thereby increasing the useful service life of the vacuum pump for discharging the exhaust gases from the film-deposition apparatus. Further, even if the heating trap device is located in proximity to the film-deposition apparatus, flaked-off particles are not problematic. Hence, it is unnecessary to heat various piping. Thus, it is possible to reduce power consumption and avoid complicating the overall heating-type trap device.

According to the present invention, the trap temperature-presetting mechanism includes a heat insulating mechanism for thermally insulating the heaters from an exterior of the heating-type trap device. With this configuration, heat dissipation is reduced from the trap device toward an exterior thereof, thereby further cutting back power consumption. Also, according to the present invention, the heat insulating mechanism is defined by a heat insulating space kept in a vacuum state. With this configuration, it is possible to reduce power consumption and there is no danger of contaminants due to heat insulating materials filling this space.

Also, according to the present invention, at least the plate-like heater of the plate-like heater and its supporting member are made of SiC material. In this case, when the SiC material is energized, it is heated and functions as a heater. Also, it is possible to inductively heat the SiC material, thereby heating the plate-like heater effectively.

Also, according to the present invention, the heating-type trap device is disposed in proximity to an exhaust gas hole of a film-deposition chamber. With this configuration, since the residual film-deposition gases reach the trap device before being cooled, the development of reacted by-products can be moderately reduced. Furthermore, it can minimize a region which is located on the way of the piping toward an exhaust system and apt to cool the residual film-deposition gases. Thus, a tape-like heater is prevented from being wound around the piping, and the process steps for assembling the device are reduced.

Also, according to the present invention, the heating-type trap device preferably has an outer diameter substantially similar to that of the exhaust piping having an exhaust hole to which the trap device is connected. With this configuration, even if the heating-type trap device is disposed in proximity to the exhaust hole immediately adjacent to the film-deposition chamber, the heating-type trap device will not protrude much, thereby reducing space for its installation. Therefore, there is little danger of the device being an obstacle which will obstruct workers, thereby improving operability.

Also, according to the present invention, the heat insulating space is evacuated by a vacuum pump for discharging exhaust gases through the exhaust piping. With this configuration, the vacuum pump is used also as a vacuum pump for evacuating the heat insulating space, thereby reducing a manufacturing cost of the device.

Also, according to the present invention, the trap temperature-presetting means includes a temperature controller for controlling an interior temperature of the heating-type trap device to match a desired temperature. In this case, the temperature controller can control the heater temperature substantially to around a preset temperature and turn on/off power supply to the heater to match the user's desired heating. With this configuration, a desired film-deposition can be accomplished in the trap device, and a required power supply can be minimized. As a result, energy can be saved.

Also, according to the present invention, the temperature controller can preset the interior temperature of the heating-type trap device depending on the type of film-deposition gases which are supplied to the film-deposition chamber. With this configuration, it is possible to control a crystalline state of the film deposited within the heating-type trap device so as to form a strongly deposited film, thereby preventing the film from flaking-off as particles.

Also, the film-deposition apparatus in accordance with the present invention includes a heating-type trap device which is disposed between a film-deposition chamber into which reactive gases are supplied for a film-deposition, and an exhaust piping for discharging exhaust gases from the film-deposition chamber. With this configuration, it is possible to provide a film-deposition apparatus equipped with a heating-type trap device exhibiting the advantageous operations and effects as mentioned above.

The present application relates to Japanese Patent Application (JPA) 10-171678 filed on Jun. 18, 1998, and to JPA 11-144662 filed on May 29, 1999, each incorporated herein by reference in their entireties.

### BRIEF DESCRIPTION OF THE DRAWINGS

FIG. 1 is a side cross-sectional view of a film-deposition apparatus and a heating-type trap device 50 disposed downstream of a film-deposition apparatus according to the present invention;

FIG. 2 is an enlarged side cross-sectional view of the heating-type trap device 50 of FIG. 1;

FIG. 3 is a side cross-sectional view of a conventional film-deposition apparatus;

FIG. 4(a) is a side cross-sectional view of a conventional water-cooled trap device equipped with an exhaust piping connected thereto;

FIG. 4(b) is a cross-sectional view taken along a line A-A in FIG. 4(a);

FIG. 5 is a side cross-sectional view of a conventional multi-trap device which does not use cooling water and is equipped with an exhaust piping connected thereto; and

FIG. 6 is a side cross-sectional view of a conventional piping heater for heating a piping extending from a film-deposition apparatus to an exhaust system.

### DETAILED DESCRIPTION OF THE PREFERRED EMBODIMENT OF THE PRESENT INVENTION

Hereinafter, a preferred embodiment of the present invention will be described in detail with reference to the accompanying drawings.

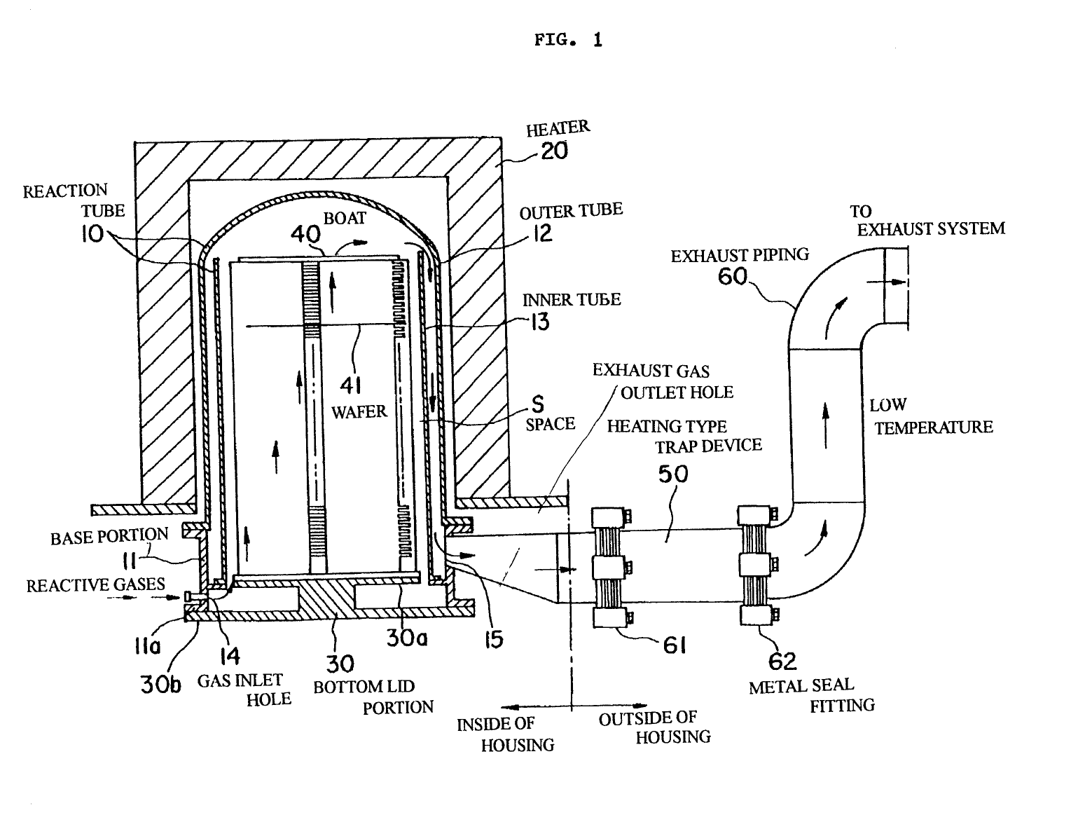

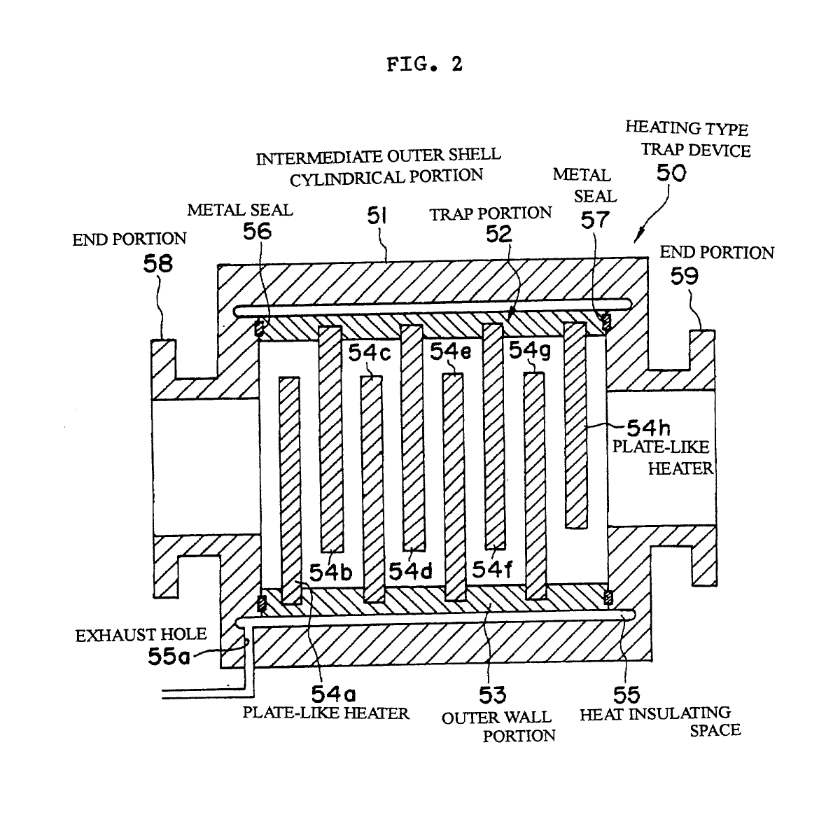

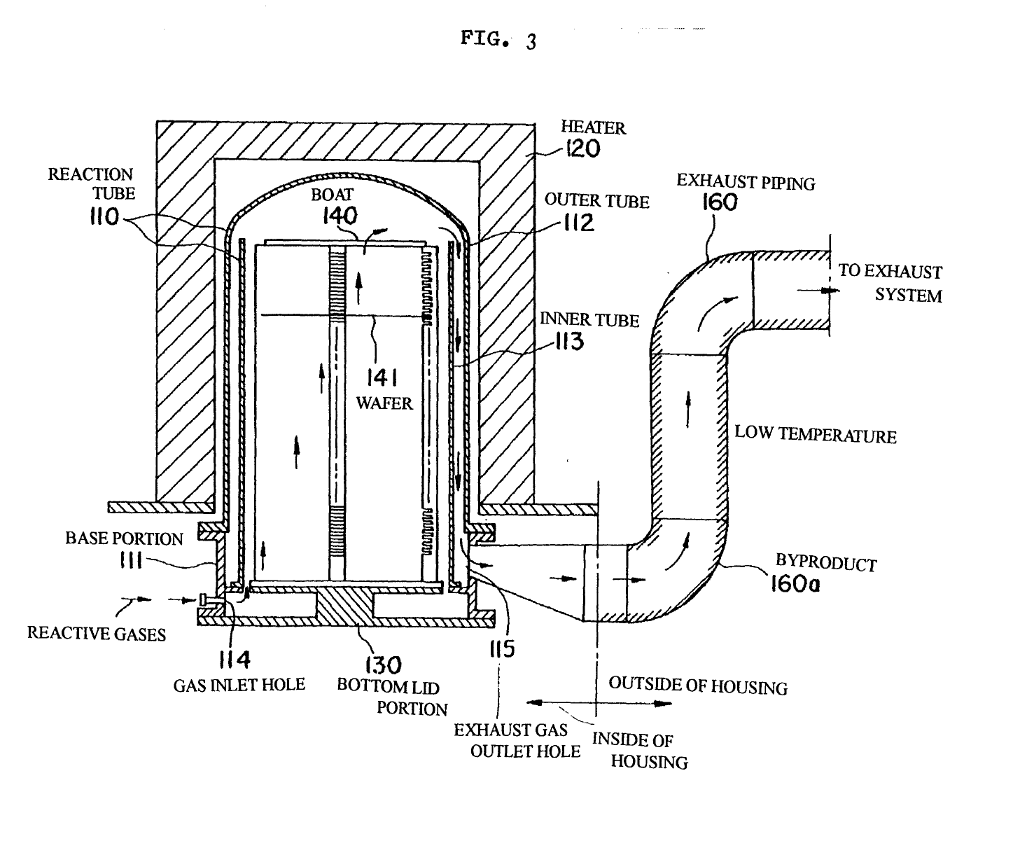

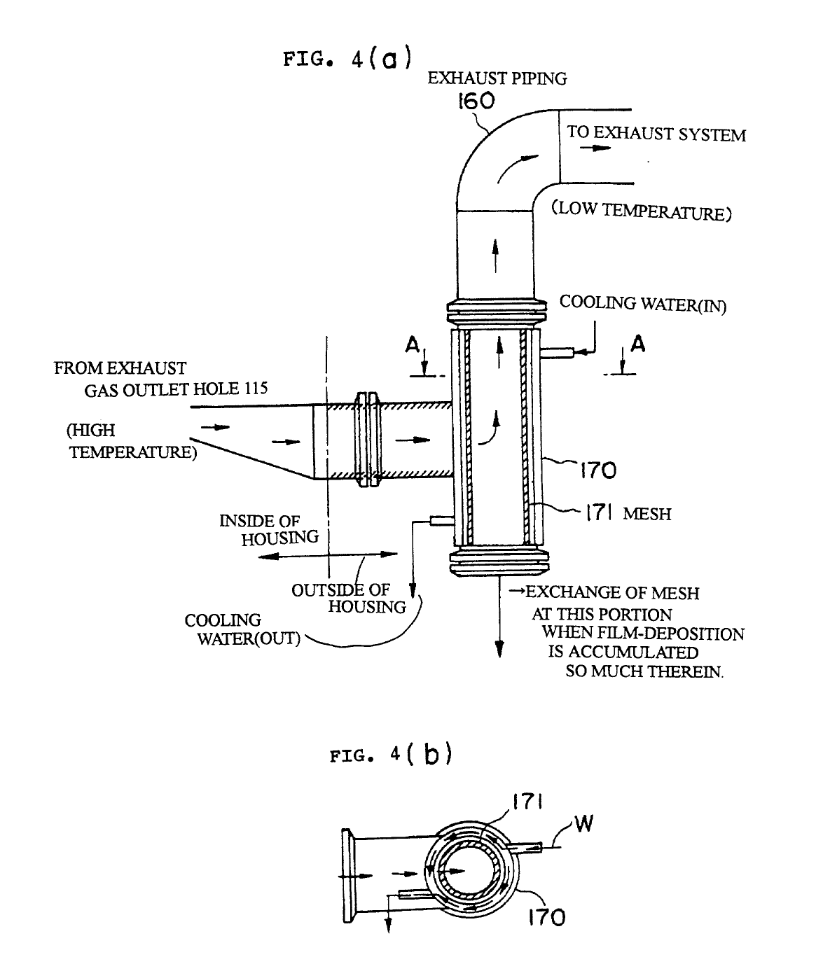

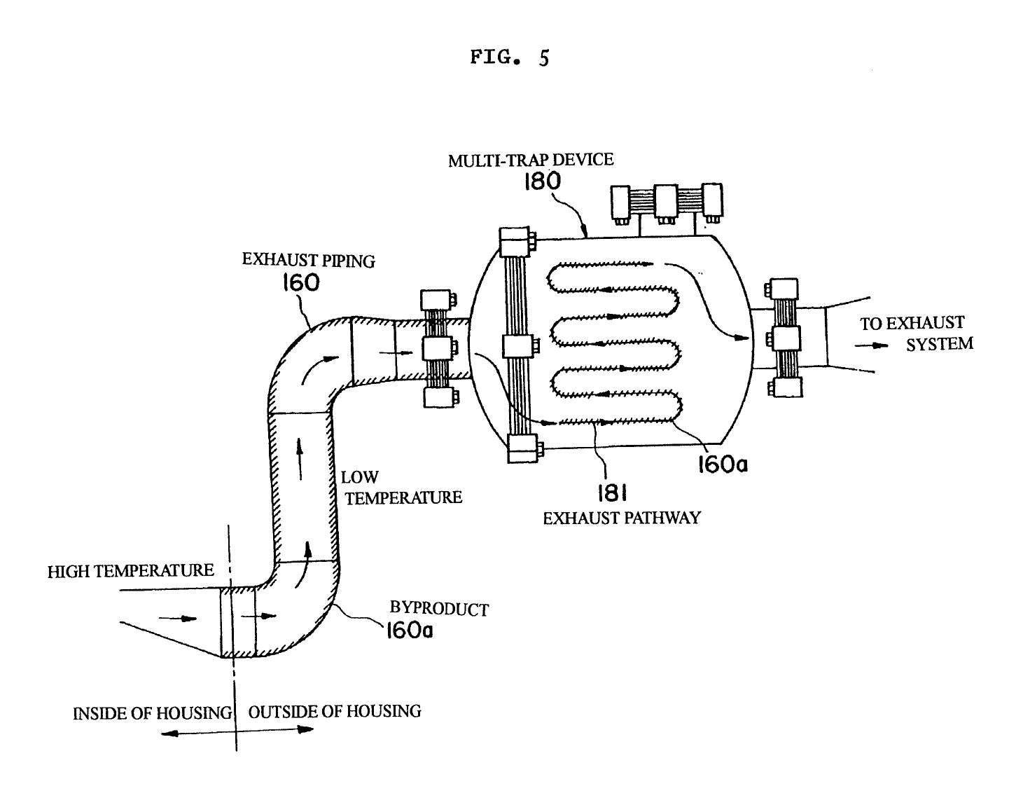

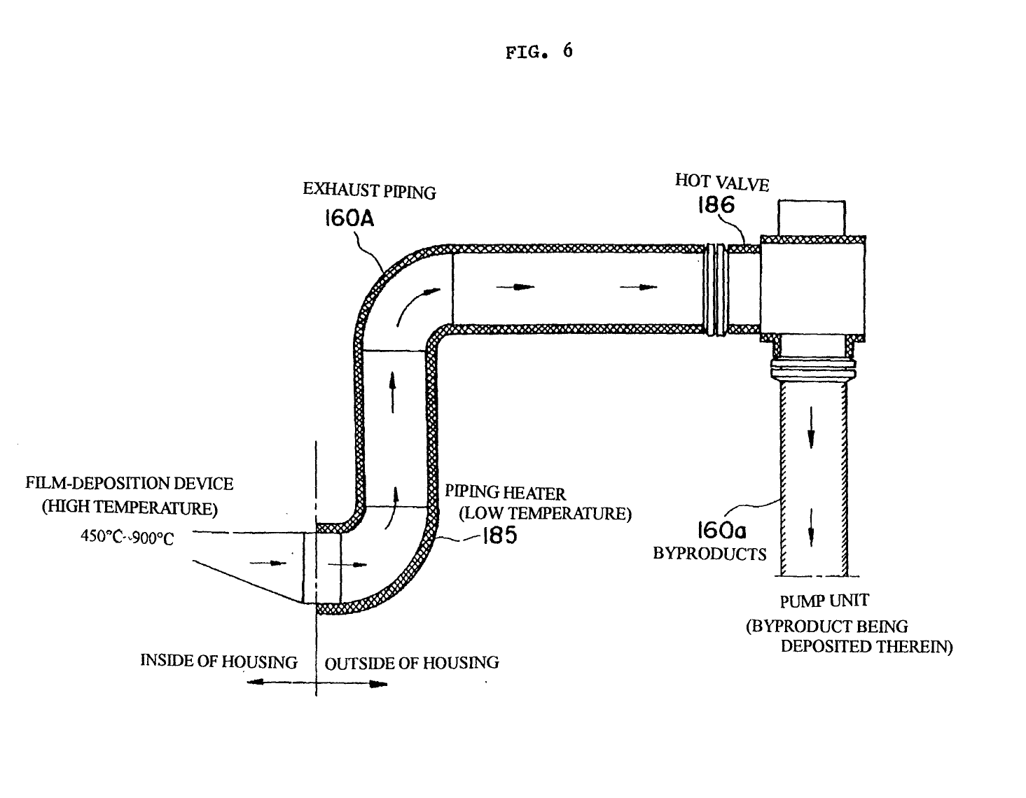

FIG. 1 shows a film deposition apparatus according to a preferred embodiment of the invention along with a heating-type trap device 50 and an exhaust piping 60 disposed downstream of the film deposition apparatus. FIG. 2 is an enlarged view showing a structure of the heating-type trap device 50 of FIG. 1. The film deposition apparatus as shown in FIG. 1 is a typical kind of vertical chemical vapor deposition (CVD) apparatus having a substantially similar structure to a structure configured between a gas inlet hole and an exhaust gas hole of a conventional vertical CVD apparatus as shown in FIG. 3.

In a vertical CVD apparatus as shown in FIG. 1, a reaction tube 10 which constitutes a film deposition chamber and has a cylindrical shape includes a base portion 11, an outer tube 12 and an inner tube 13. The base portion 11 has a cylindrical shape opening upwardly and downwardly, and includes an upper flange and a lower flange both of which are extending diametrically outwardly at its upper and lower ends, as well as an intermediate flange which is slightly extending diametrically inwardly at a middle point between the upper and lower flanges. On the upper flange of the base portion 11, there is mounted the outer tube 12 at its lower flange, whereas the inner tube 13 is at its lower flange mounted on the intermediate flange of the base portion 11 with a ring intervening therebetween for mounting the inner tube 13 on the base portion 11.

An upper end of the outer tube 12 is sealed or closed, whereas opposite ends of the inner tube 13 are in an opened state, respectively. A space or gap is provided between the outer tube 12 and the inner tube 13 to define a dual structure thereby. Around the outer tube 12, a heater arrangement 20 is disposed to heat an interior of the reaction tube 10. A bottom opening portion of the reaction tube 10 is selectively sealed by a bottom lid portion 30 (which is elevated at the highest position thereof in a state as shown in FIG. 1). On a side wall area located between the middle point and the lower end of the base portion 11, a gas inlet hole 14 is provided for introducing reactive or reactant gases therethrough, as indicated by an arrow in FIG. 1.

Also, on a side wall area which is diametrically opposed to the above-mentioned side wall area having the gas inlet hole 14 and located between the middle point and the upper end of the base portion 11, an exhaust gas outlet hole 15 is provided for exhausting or discharging exhaust gases (e.g., residual film-deposition gases) including reacted by-products and unreacted gases therethrough.

The bottom lid portion 30 includes an upper disc 30a and a lower disc 30b which are interconnected by a central post portion each of which are preferably integrally forward with one another. In operation of the vertical CVD apparatus, the bottom lid portion 30 mounting a boat 40 thereon is elevated along with a number of wafers 41 to be processed placed in the boat 40, so that the boat 40 is disposed in the inner tube 131. Then, in the highest elevated position (as shown in FIG. 1), the lower disc portion 30b of the bottom lid portion 30 abuts at its outer peripheral upper surface on the lower flange 11a of the base portion 11 to seal an interior of the reaction tube 10.

In the above configuration, a space S is provided between an outer periphery of the upper disc 30a of the bottom lid portion 30 and the inner tube 13, so as to pass reactant gases through the space S.

A heating-type trap device 50 is connected through a metal seal 56 (shown in FIG. 2) to a vicinity of the exhaust gas outlet hole 15, its connection part being fixedly sandwiched by a metal seal fitting 61. The heating-type trap device 50 is further connected through a metal seal 57 (shown in FIG. 2) to an exhaust piping 60, its connection part being also fixedly sandwiched by a metal seal fitting 62.

Referring to FIG. 2, the heating-type trap device 50 includes an intermediate outer shell cylindrical portion 51, a cylindrical trap portion 52 disposed in and coaxially with the intermediate outer shell cylindrical portion 51, and opposite end portions 58, 59 assembled with the intermediate outer shell cylindrical portion 51 and the cylindrical trap portion 52 so as to sandwich them therebetween. As shown in FIG. 1, the end portion 58 is connected through the metal seal 56 to a piping on a side of the exhaust gas outlet hole 15. The end portion 59 is connected through the metal seal 57 to the exhaust piping 60 toward an exhaust system (not shown), each of their connecting parts being fixedly sandwiched by the corresponding metal seal fittings 61, 62.

The trap portion 52 is assembled with its cylindrical outer wall portion 53, and is disposed at a constant distance (as a heat insulating space) away from an inner wall of the intermediate outer shell cylindrical portion 51, and includes opposite annular end surfaces abutting on the end portions 58, 59, respectively. Each pair of abutting surfaces interposes one of metal seals 56, 57 therebetween. In this case, the metal seals 56, 57 are employed instead of conventional O-rings (such as viton or kalrez) because the heating-type trap device 50 will be heated to a high temperature (e.g., an operating temperature range from about 450° C. to about 900° C.), as described below.

In respective abutting portions between the end portions 58, 59 and the trap portion 52, each end of a heat insulating space 55 extends to the midpoint position of a wall thickness adjacent to its corresponding abutting portion. Also, the heat insulating space 55 is in communication with an externally opened exhaust hole 55a formed at its part extending into the end portion 58. From the exhaust hole 55a, the heat insulating space 55 is evacuated to a vacuum to prevent heat from escaping exteriorly, and simultaneously to prevent contaminants from occurring, thereby reducing power consumption. Of course, the heat insulating space 55 may be filled with suitable heat insulating materials instead of being merely in a vacuum.

The trap portion 52 includes a plurality of heating plates 54a, 54b, . . . , 54h (e.g., made of SiC material), each of which is partially embedded or implanted at one side thereof into an inner wall of the outer wall portion 53 while being separated at the other side thereof from the same inner wall but diametrically opposed thereto, so that they are arranged in parallel with each other and perpendicular to a central axis of the trap portion 52. It will be appreciated to those skilled in the art that adjacent heating plates of the above example, as shown in FIG. 2, are implanted alternatively in the opposite inner wall parts to define a zigzag or repetitive folded-back pathway for gases passing therethrough. However, the arrangement of heating plates is not limited to that as shown in FIG. 2. Further, preferably the heating plates have the same dimensions, but of course the heating plates could also have different dimensions.

In operation of the heating-type trap device 50, exhaust gases discharged from the exhaust gas hole 15 are heated by heating plates 54a, 54b, . . . , 54h to a temperature equal to or greater than a temperature in the interior of the reaction tube 10 (e.g., a typical temperature at about 600° C., or a temperature ranging from about 450° C. to about 900° C. depending on the kinds of film-deposition gases). With this heating operation, reacted byproducts and unreacted gases will be deposited to strongly adhere, for example, onto heating plates 54a, 54b, . . . , 54h within the heating-type trap device 50.

Types of reactive gases (film-deposition gases) used for obtaining an objective film to be deposited and a temperature in the interior of the reaction tube 10, (i.e., a temperature in the interior of the trap portion 52) are as follows:

TABLE 1

| | | | Temperature in | |
|---|---|---|---|---|
| Objective film to be deposited | Reactive gases | | Reaction tube | |
| Poly-Si film | SiH₄ | | 620° C. | |
| Doped Poly-Si film | SiH₆ | + PH₃ | 540° C. | to 650° C. |
| SiO₂ film | Si₂H₆ | + N₂O | 450° C. | to 800° C. |
| Si₃N₄ film | SiH₂Cl₂ | + NH₃ | 680° C. | to 800° C. |

In this case, it is possible to freely control a temperature switching by using a control program in a control portion (not shown). In the above embodiment, a preset temperature of the trap portion 52 is equal to or greater than the interior temperature of the reaction tube 10, as described above. This is because such a preset temperature permits residual film-deposition components to be maximally deposited on the trap portion 52. However, obviously it may be necessary to adjust the preset temperature more or less in keeping with an actual situation.

Thus, by using the residual film-deposition gases discharged through the exhaust gas hole 15 from the reaction tube 10 of the vertical chemical vapor deposition apparatus, a film-deposition process is performed in the heating-type trap device 50 which is put under an environment similar to that for the reaction tube 10. Accordingly, the residual film-deposition gas components will be deposited as a film (especially on the heating plates) in the trap portion 52 of the heating-type trap device 50, so that the deposited film is not easily flaked-off.

Thus, the film deposited on trap portions (or heating plates) does not flake-off from the trap portions and are not scattered (reversely diffused) into the reaction tube 10. As a result, the interior of the reaction tube 10 is not contaminated. Accordingly, even if the heating trap device 10 is located in proximity of the exhaust gas hole 15 of the vertical chemical vapor deposition apparatus, no problem results. Also, a significant reduction of the residual film-deposition components can be realized in exhaust gases discharged from the heating-type trap device 50. Thus, due to such exhaust gases, a significant reduction of deposition in the exhaust piping 60 and a vacuum pump (not shown) positioned downstream from the heating-type trap device 50 can be realized, thereby increasing useful service lives of various downstream components.

Various heating methods may be used such as radio heating, electrical heating, or electrostatic heating for heating the heating plates 54a, 54b, . . . , 54h of the heating-type trap device 50. In this case, the heating plates are preferably arranged to improve heating efficiency. It will be appreciated to those skilled in the art that the trap portion 52 of the heating-type trap device 50 is not limited to a cylindrical shape as in this embodiment, but instead, it may have a rectangular cross-sectional shape. Preferably, the number of heating plates is as high as possible within a range suitable for exhaust performance to maximize a total area for contacting the residual film-deposition gases. In the example shown in FIG. 2, the heating plates 54a, 54b, . . . , 54h form a zigzag or folded-back (e.g., snake-like or serpentine) pathway of gases within the trap portion 52 to lessen exhaust conductance so that the trapping effect with respect to the residual film-deposition gases is improved.

In this embodiment, an outline of the heating-type trap device 50 is made substantially equal to that of the exhaust piping 60, to use an installation space efficiently equipment's installation. However, if there is a sufficient space, the size of the heating-type trap device 50 may be increased to be greater than that of the exhaust piping 60. When the heat insulating space 55 between the outer wall portion 53 and the intermediate outer shell cylindrical portion 51 of the trap portion 52 is evacuated to a vacuum, the above-mentioned vacuum pump (not shown) for discharging gases through the exhaust piping 60 from the film-deposition apparatus can be employed therefor at no extra cost.

Further, a heating device for heating the trap portion 52 may be designed to include a temperature controller for precisely controlling its heating temperature to match a reference or desired temperature. Also, the reference temperature can be changed or switched depending upon the kinds of film-deposition gases to be used. Furthermore, an assembly of the trap portion 52 should be designed to be partially disassembled (e.g., modular) for easy maintenance.

As is clear from the above description, the present invention provides a trap device and a film-deposition apparatus at a moderate manufacturing cost, the trap device of which is capable of surely or sufficiently depositing residual film-deposition components and the like on a trap portion. As a result, an interior of the film-deposition apparatus is prevented from being contaminated by flaked-off particles, without increasing the size and complexity of the overall trap device for trapping the residual film-deposition components and without additional facilities for trapping the residual film-deposition components and the like.

While the invention has been described in terms of a preferred embodiment, those skilled in the art will recognize that the invention can be practiced with modification within the spirit and scope of the appended claims.

What is claimed is:

1. A heating-type trap device for being fitted in between a film-deposition apparatus and an exhaust piping, and for removing residual film-deposition components from exhaust gases discharged through the exhaust piping from the film-deposition apparatus, comprising:
a trap portion for receiving the exhaust gases; and
a plurality of plate heaters disposed within the trap portion, to define a zigzag pathway for the exhaust gases passing therethrough.

2. A heating-type trap device as claimed in claim 1, wherein said plate heaters are arranged so as to form a trap temperature presetting means for presetting an interior temperature of said heating-type trap device at a temperature equal to or greater than a film-deposition temperature of the film-deposition apparatus.

3. A heating-type trap device as claimed in claim 2, wherein said trap temperature presetting means includes heat insulating means for thermally insulating the heating-type trap device from an exterior thereof.

4. A heating-type trap device as claimed in claim 3, wherein said heat insulating means is defined by a heat insulating space kept in a vacuum state.

5. A heating-type trap device as claimed in claim 1, further comprising a support member respectively provided for each of said heaters, wherein at least one of said heaters and its supporting member is made of SiC.

6. A heating-type trap device as claimed in claim 1, wherein said heating-type trap device is disposed in proximity to an exhaust gas hole of said film-deposition chamber.

7. A heating-type trap device as claimed in claim 6, wherein said heating-type trap device has an outer diameter substantially similar to that of said exhaust piping having an exhaust hole to which said trap device is connected.

8. A heating-type trap device as claimed in claim 4, wherein said heat insulating space is evacuated by a vacuum pump used for discharging the exhaust gases through the exhaust piping.

9. A heating-type trap device as claimed in claim 2, wherein said trap temperature presetting means includes a temperature controller for controlling the interior temperature of said heating-type trap device to match a desired temperature.

10. A heating-type trap device as claimed in claim 9, wherein said temperature controller selectively presets the interior temperature of said heating-type trap device depending on kinds of film-deposition gases which are supplied to said film-deposition chamber.

11. A heating-type trap device as claimed in claim 1, wherein said plate heaters are arranged so as to form a trap temperature presetting unit for presetting an interior temperature of said heating-type trap device at a temperature equal to or greater than a film-deposition temperature of the film-deposition apparatus.

12. A heating-type trap device as claimed in claim 11, wherein said trap temperature presetting unit includes a heat insulating mechanism for thermally insulating the heating-type trap device from an exterior thereof.

13. A heating-type trap device as claimed in claim 12, wherein said heat insulating mechanism comprises a heat insulating space kept in a vacuum state.

14. A heating-type trap device as claimed in claim 11, wherein said trap temperature presetting unit includes a temperature controller for controlling the interior temperature of said heating-type trap device to match a desired temperature.

15. A heating-type trap device as claimed in claim 14, wherein said temperature controller selectively presets the interior temperature of said heating-type trap device depending on kinds of film-deposition gases which are supplied to said film-deposition chamber.

16. A film-deposition apparatus comprising:
a film deposition chamber;
a heating-type trap device as claimed in claim 1 coupled at a first portion thereof to an output of said film-deposition chamber to which reactive gases are supplied for a film-deposition; and
an exhaust piping, coupled to a second portion of said trap device, for discharging exhaust gases from said film-deposition chamber.

17. A film deposition apparatus, comprising:
a film-deposition chamber; and
a heating-type trap device for receiving an output from said film-deposition chamber, and for removing residual film-deposition components from exhaust gases discharged from the film-deposition apparatus,
said trap device comprising:
a trap portion; and
a plurality of plate heaters disposed within the trap portion to define an irregular pathway for passing the exhaust gases therethrough.

18. The apparatus according to claim 17, wherein said pathway has a zigzag shape, and
wherein said plate heaters are arranged so as to form a trap temperature presetting mechanism for presetting an interior temperature of said trap device at a temperature equal to or greater than a film-deposition temperature of the film-deposition apparatus.
